(19) United States
(12) Patent Application Publication
(10) Pub. No.: US 2026/0053060 A1
(43) Pub. Date: Feb. 19, 2026

(54) ELECTRONIC DEVICES AND METHODS OF MANUFACTURING ELECTRONIC DEVICES

(71) Applicant: Amkor Technology Singapore Holding Pte. Ltd., SG - SINGAPORE (SG)

(72) Inventors: Wang Gu Lee, Seoul (KR); Kyun Ahn, Gyeonggi-do (KR); In Su Mok, Incheon (KR)

(73) Assignee: Amkor Technology Singapore Holding Pte. Ltd., SG - SINGAPORE (SG)

(21) Appl. No.: 18/805,348

(22) Filed: Aug. 14, 2024

(51) Int. Cl. H01L 25/10; H01L 23/00; H01L 23/31; H01L 23/498; H01L 23/538; H01L 25/00

(52) U.S. Cl. CPC H01L 25/105; H01L 23/49811; H01L 23/5383; H01L 24/08; H01L 24/80; H01L 25/50; H01L 23/3107; H01L 2224/08225; H01L 2224/80095; H01L 2224/80895; H01L 2224/80896; H01L 2225/1041

(57) ABSTRACT

In one example, a device includes a redistribution layer (RDL) substrate comprising a first side and a second side opposite the first side. A wafer component can be coupled to the first side of the RDL substrate. A first bond interface can be disposed between the wafer component and the RDL substrate. The first bond interface can be provided by a first hybrid bond. An electronic component can be coupled to the second side of the RDL substrate. A second bond interface can be disposed between the electronic component and the RDL substrate. The second bond interface can be within a footprint of the first bond interface and can be provided by a second hybrid bond. A vertical interconnect can be disposed lateral to a sidewall of the electronic component. The vertical interconnect can be coupled to the RDL substrate. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2S show an example method for manufacturing an electronic device.

FIG. 3 shows a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in the present disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by one or more intervening element(s) C. Similarly, the terms “over” or “on” may be used to describe two elements directly contacting each other or describe two elements indirectly coupled by one or more other elements. As used herein, the term “coupled” can refer to a mechanical coupling and/or an electrical coupling.

### DESCRIPTION

An example electronic device can include a substrate comprising a distal side including a distal passivation and a distal terminal. The substrate can further comprise a proximate side opposite the distal side with the proximate side including a proximate passivation, a first proximate terminal, and a second proximate terminal. A wafer component can include a wafer-external passivation coupled to the distal passivation and comprising a wafer terminal coupled to the distal terminal. A first bond interface can be disposed between the wafer-external passivation and the distal passivation. The first bond interface can be disposed between the wafer terminal and the distal terminal. An electronic component can include a component-external passivation coupled to the proximate passivation, the component-external passivation including a component terminal coupled to the first proximate terminal. A second bond interface can be disposed between the component-external passivation and the proximate passivation. The second bond interface can be disposed between the component terminal and the first proximate terminal. A vertical interconnect can be disposed lateral to a side of the electronic component, and the vertical interconnect can be coupled to the second proximate terminal.

In various examples, a device interconnect can be coupled to the vertical interconnect, and a base substrate can be coupled to the device interconnect. The wafer component can comprise an active region including a front-end of line (FEOL) region and a back-end of line (BEOL) region adjacent the FEOL region. The BEOL region can comprise the wafer-external passivation and the wafer terminal. The wafer component can include an input/output component, and the electronic component can comprise a compute component. The electronic component can include an active region comprising a FEOL region and a BEOL region adjacent the FEOL region. The BEOL region can include the component-external passivation and the component terminal. The first bond interface can be formed using a first hybrid bonding process, and the second bond interface can be formed using a second hybrid bonding process. An encapsulant can be disposed around lateral sides of the electronic component and lateral sides of the vertical interconnect. The first proximate terminal can include a seed layer. The first bond interface can be disposed between the seed layer and the component terminal. The second proximate terminal can include a seed layer, and the vertical interconnect can be coupled to the seed layer.

Another example of an electronic device includes a redistribution layer (RDL) substrate comprising a first side and a second side opposite the first side. A wafer component can be coupled to the first side of the RDL substrate. A first bond interface can be disposed between the wafer component and the RDL substrate. The first bond interface can be provided by a first hybrid bond. An electronic component can be coupled to the second side of the RDL substrate. A second bond interface can be disposed between the electronic component and the RDL substrate. The second bond interface can be within a footprint of the first bond interface, and the second bond interface can be provided by a second hybrid bond. A vertical interconnect can be disposed lateral to a sidewall of the electronic component. The vertical interconnect can be coupled to the RDL substrate. An encapsulant can be disposed around the electronic component and around the vertical interconnect.

An example method of manufacturing a semiconductor device can include the step of providing a substrate including a distal side comprising a distal passivation and a distal terminal. The substrate can include a proximate side opposite the distal side with the proximate side comprising a proximate passivation, a first proximate terminal, and a second proximate terminal. A wafer component can be provided and can include a wafer-external passivation over the distal passivation and a wafer terminal over the distal terminal. A first heat can be applied to form a first bond interface between the wafer-external passivation and the distal passivation and between the wafer terminal and the distal terminal. An electronic component can include a component-external passivation over the proximate passivation and a component terminal over the first proximate terminal. A second heat can be applied to form a second bond interface between the component-external passivation and the proximate passivation and between the component terminal and the first proximate terminal. A vertical interconnect can be provided lateral to a sidewall of the electronic component and coupled to the second proximate terminal. In various examples, an encapsulant can be provided on the sidewall of the electronic component and on sidewalls of the vertical interconnect. The first heat can range from 25 degrees Celsius to 400 degrees Celsius.

Other examples are included in the present disclosure. Such examples may be found in the figures, in the claims, or in the description of the present disclosure.

Various examples of electronic devices may include solderless bonds to improve pitch and electronic communication. A signal path may begin at an external interconnect and may cross one or more hybrid bond interfaces. In some examples, the signal may reach a compute device without crossing a through-silicon via (TSV). An input/output (I/O) wafer may be disposed at an outer side of an electronic device, and a compute wafer may be buried beneath the I/O wafer to enable outsourced semiconductor assembly and test (OSAT) of face-to-back (F2B) devices.

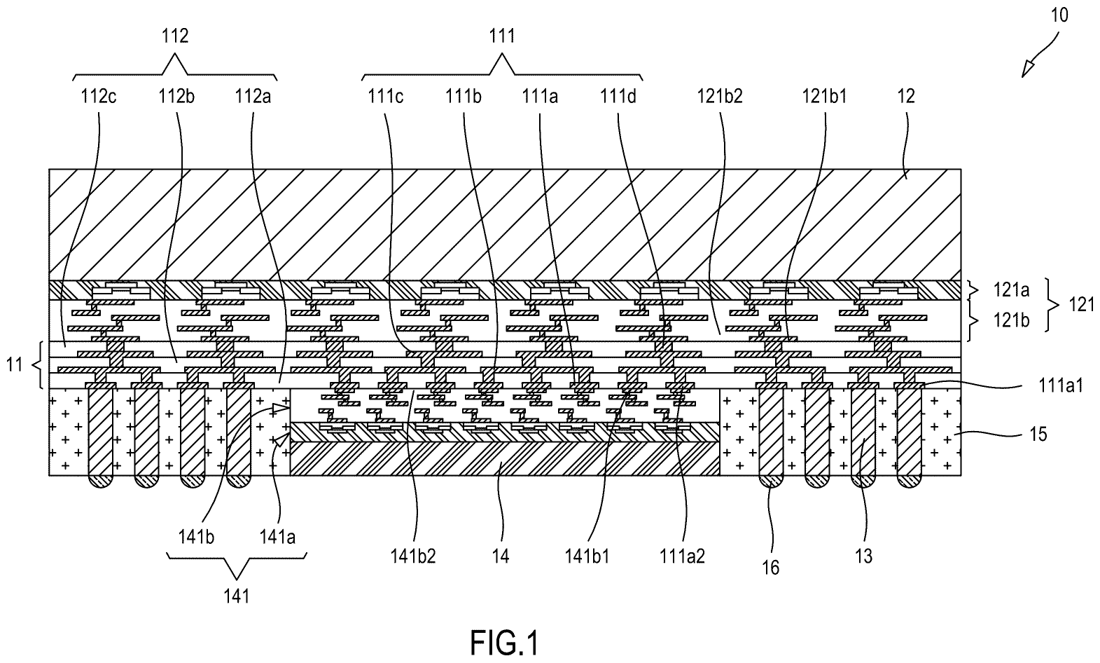

FIG. 1 shows a cross-sectional view of an example electronic device 10. In the example shown in FIG. 1, electronic device 10 can comprise RDL substrate 11, wafer component 12, vertical interconnects 13, electronic component 14, encapsulant 15, and device interconnects 16.

RDL substrate 11 can comprise conductive structure 111 and dielectric structure 112. Conductive structure 111 can comprise proximate conductive pattern 111a, intermediate conductive patterns 111b and 111c, and distal conductive pattern 111d. Proximate conductive pattern 111a can comprise first proximate terminals 111a1 and second proximate terminals 111a2. Dielectric structure 112 can comprise proximate passivation 112a, intermediate passivation 112b, and distal passivation 112c.

Wafer component 12 comprises wafer active area 121. Wafer active area 121 can comprise wafer FEOL area 121a and wafer BEOL area 121b. Wafer BEOL area 121b can comprise wafer terminals 121b1 and wafer-external passivation 121b2. In some examples, wafer component 12 can comprise an I/O wafer.

Electronic component 14 includes component active area 141. Component active area 141 can comprise component FEOL area 141a and component BEOL area 141b. Component BEOL area 141b can comprise component terminals 141b1 and component-external passivation 141b2. In some examples, electronic component 14 can comprise a compute component.

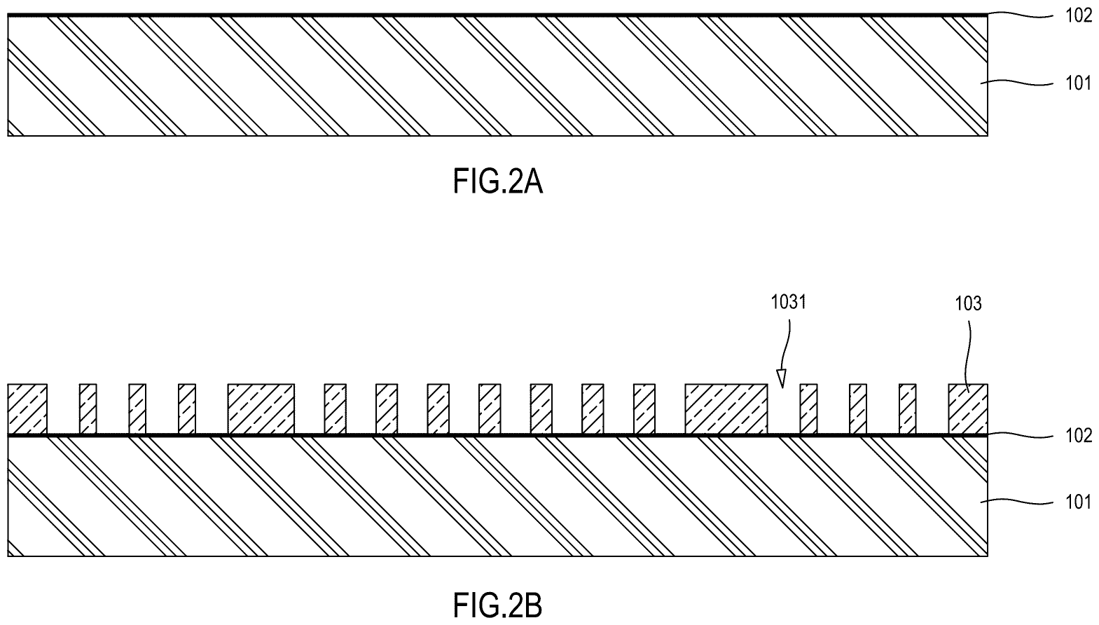

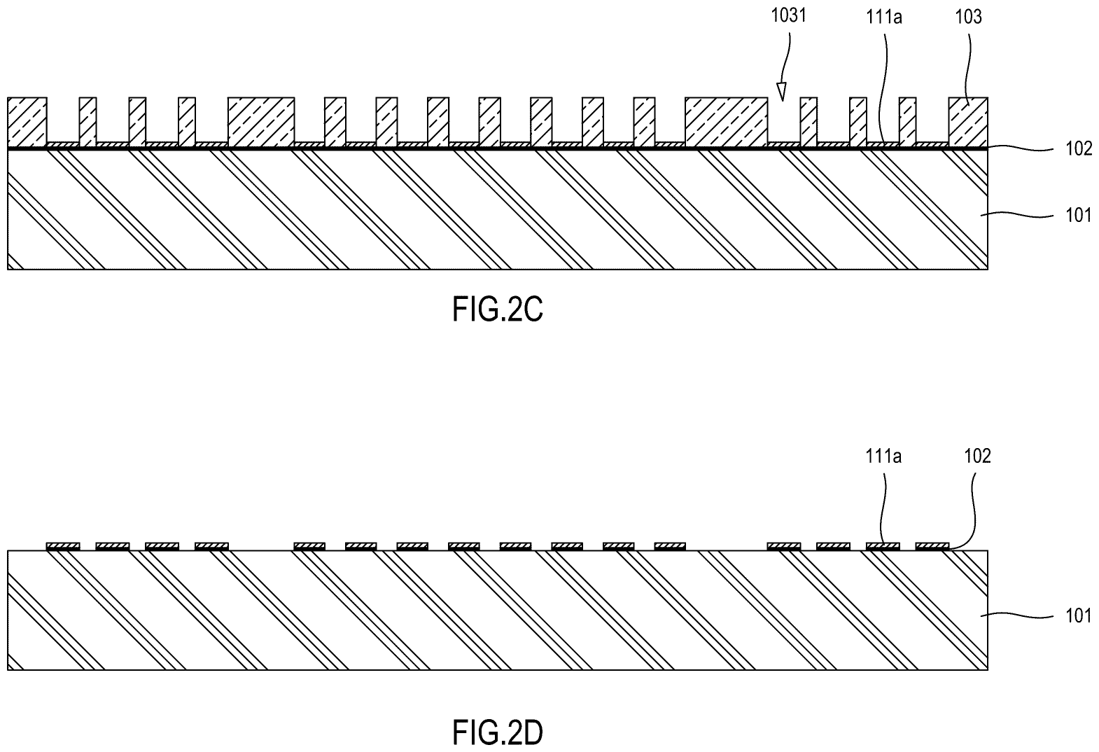

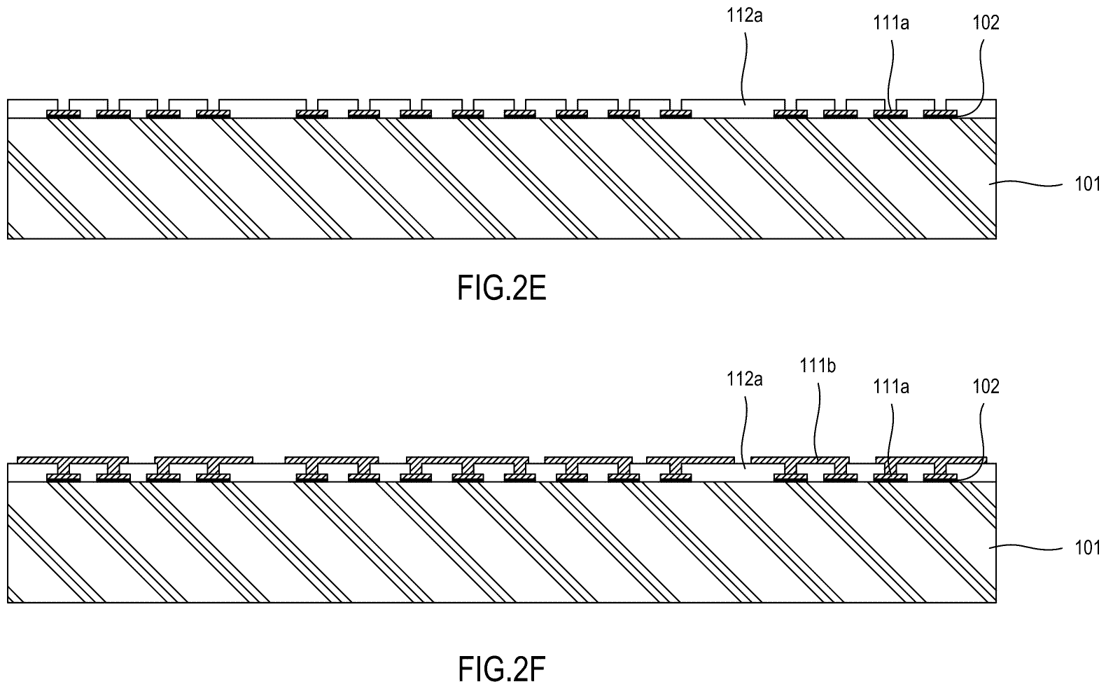

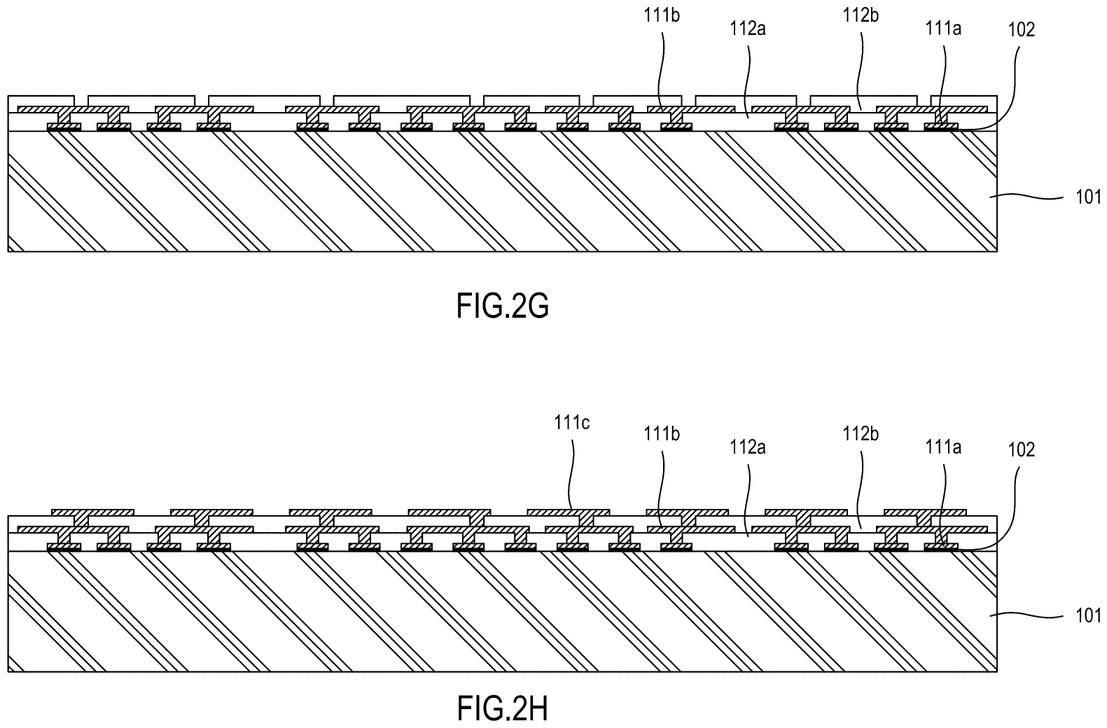

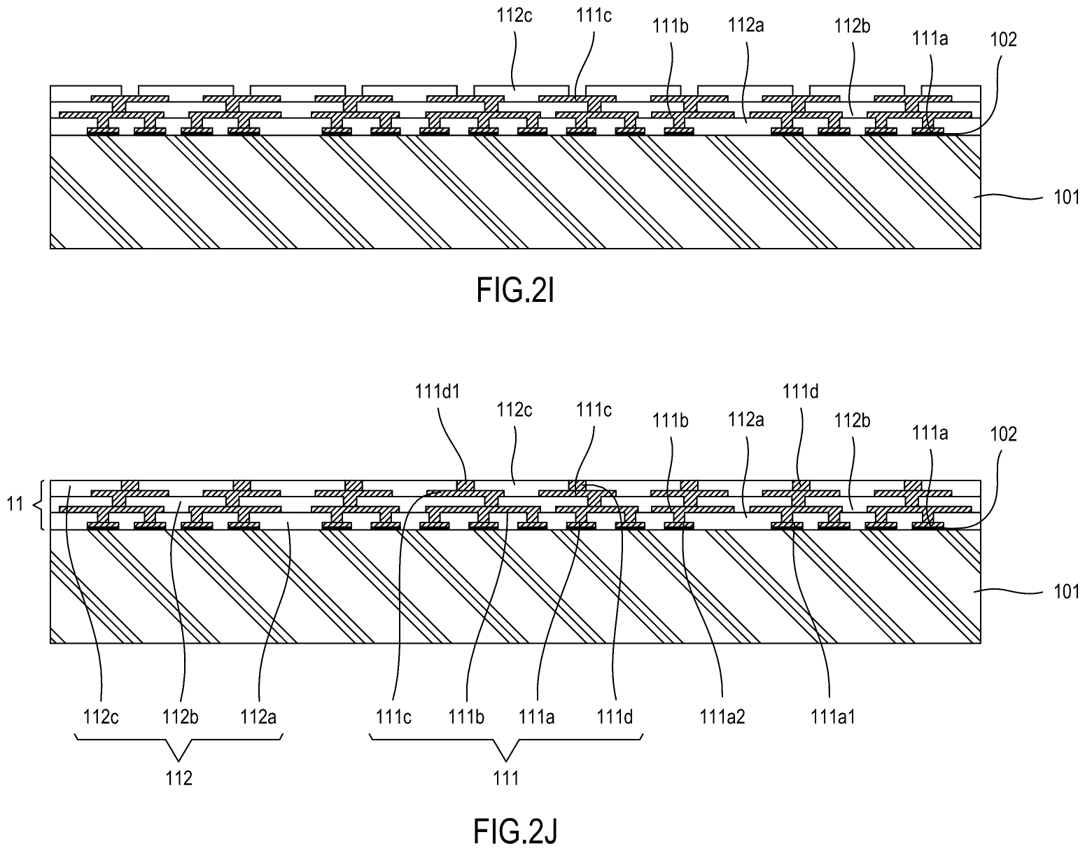

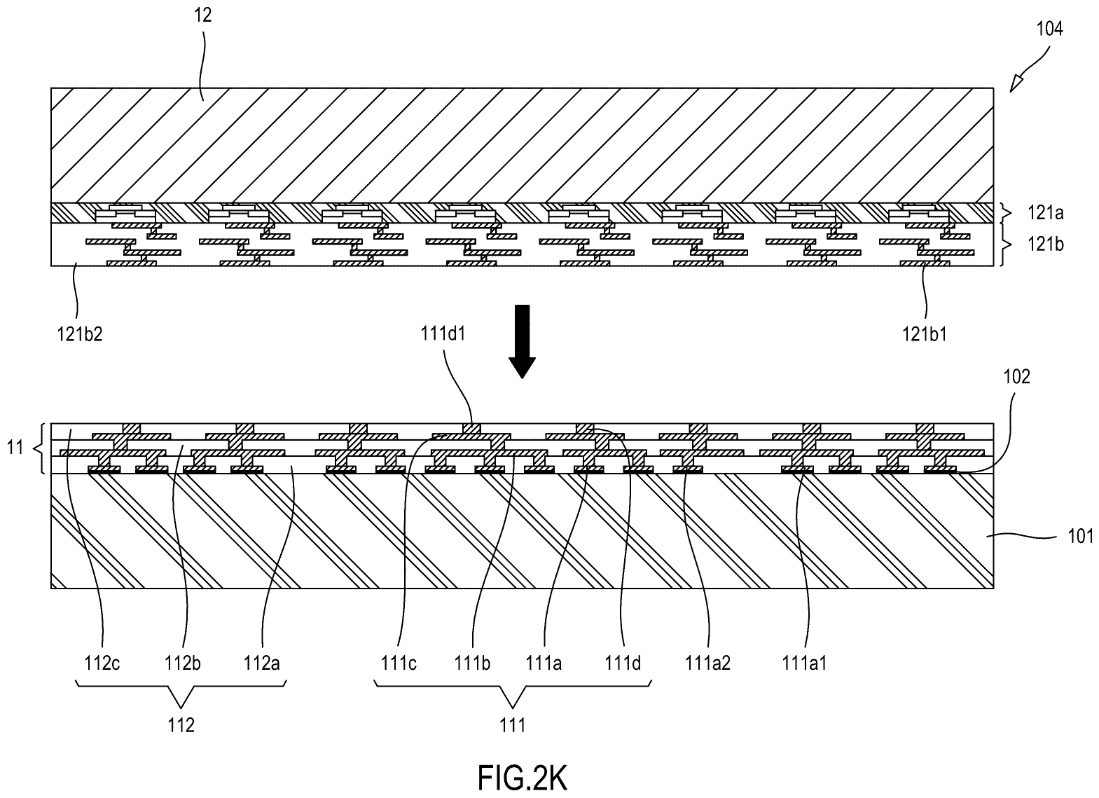

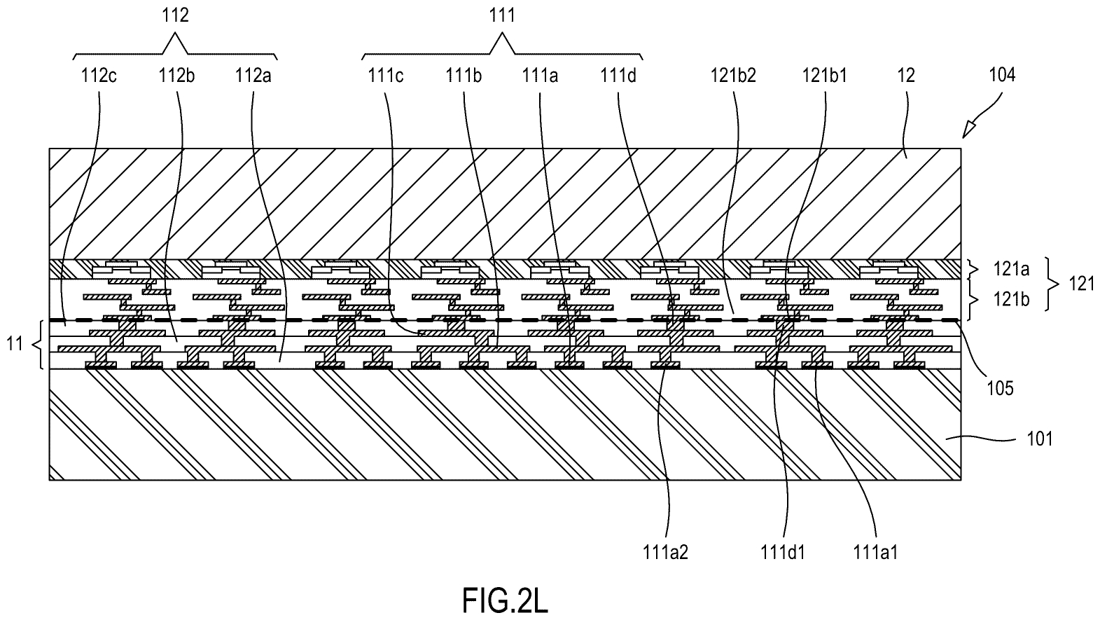

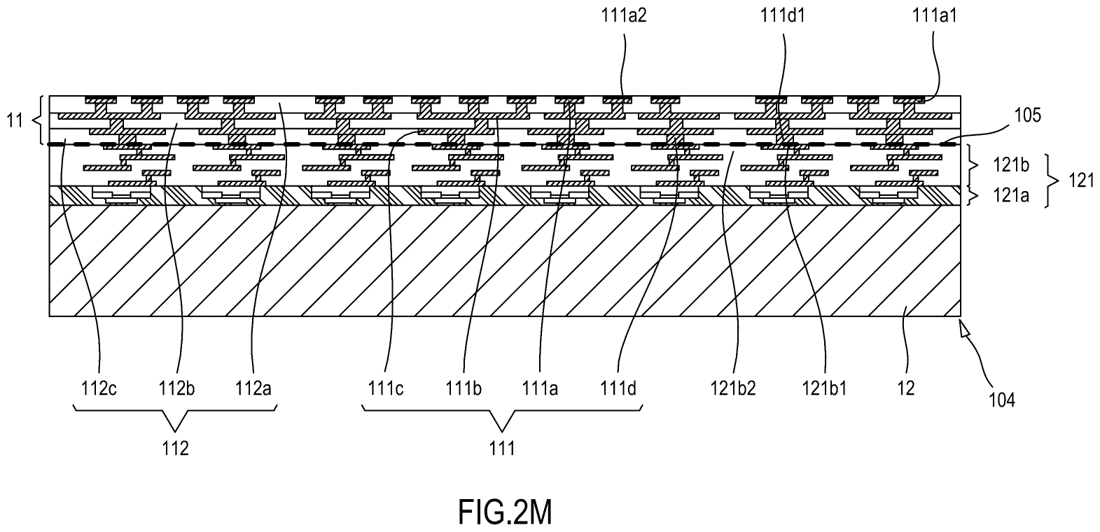

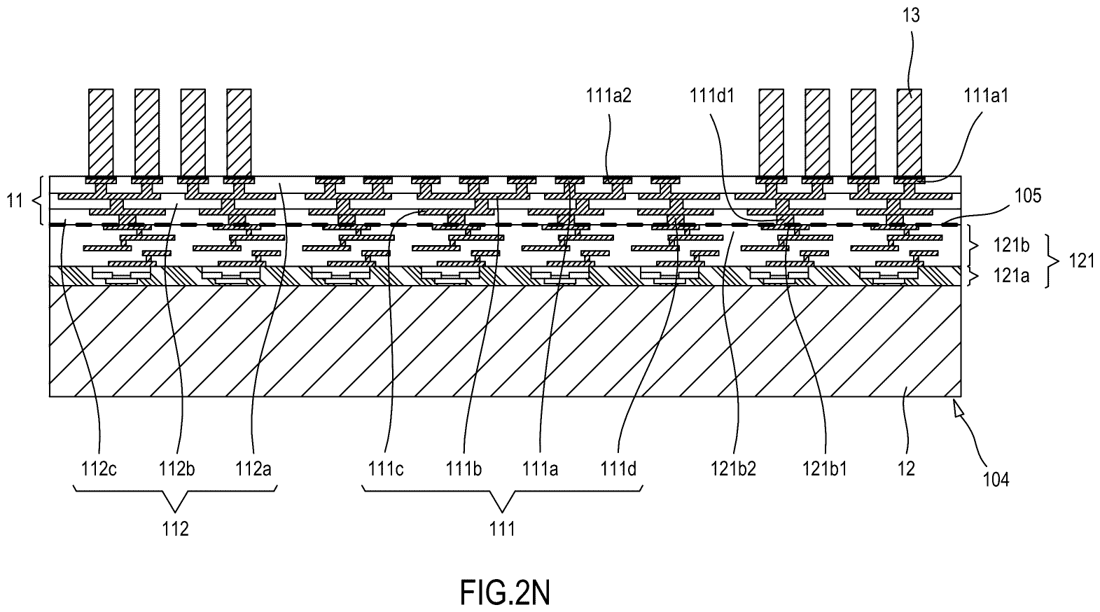

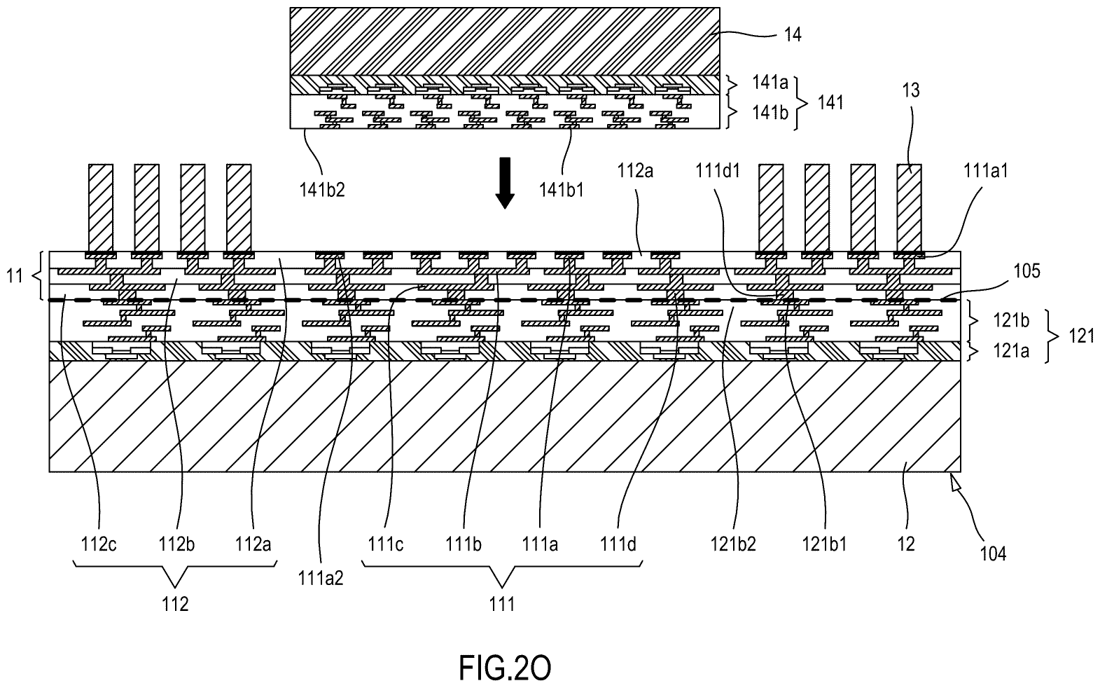

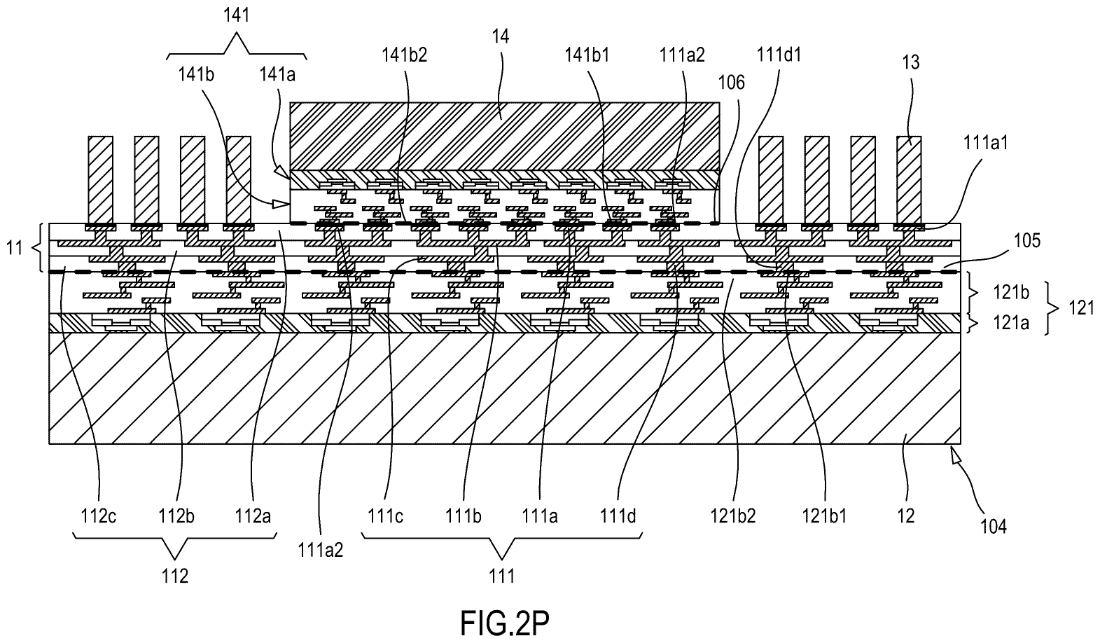

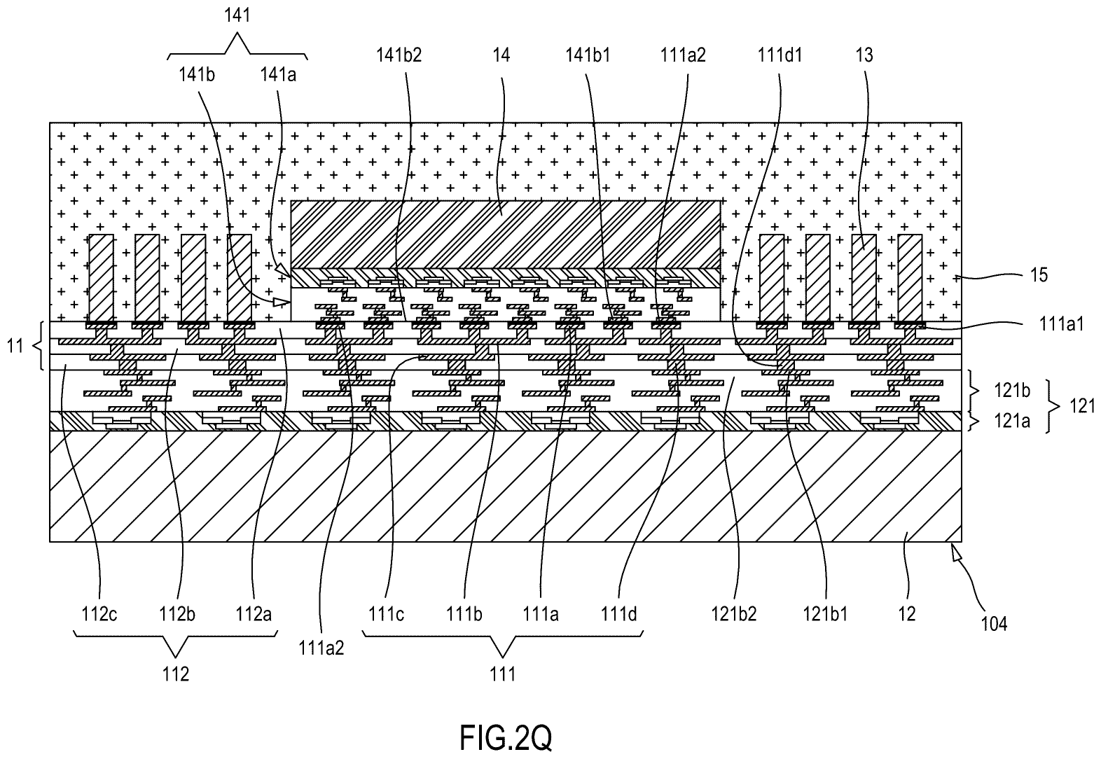

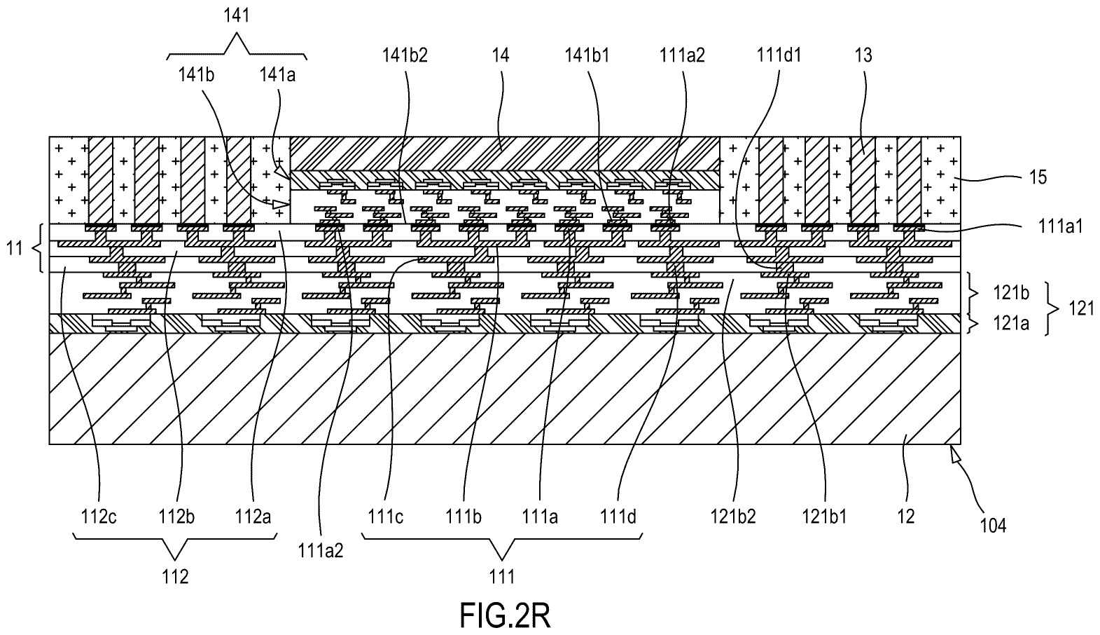

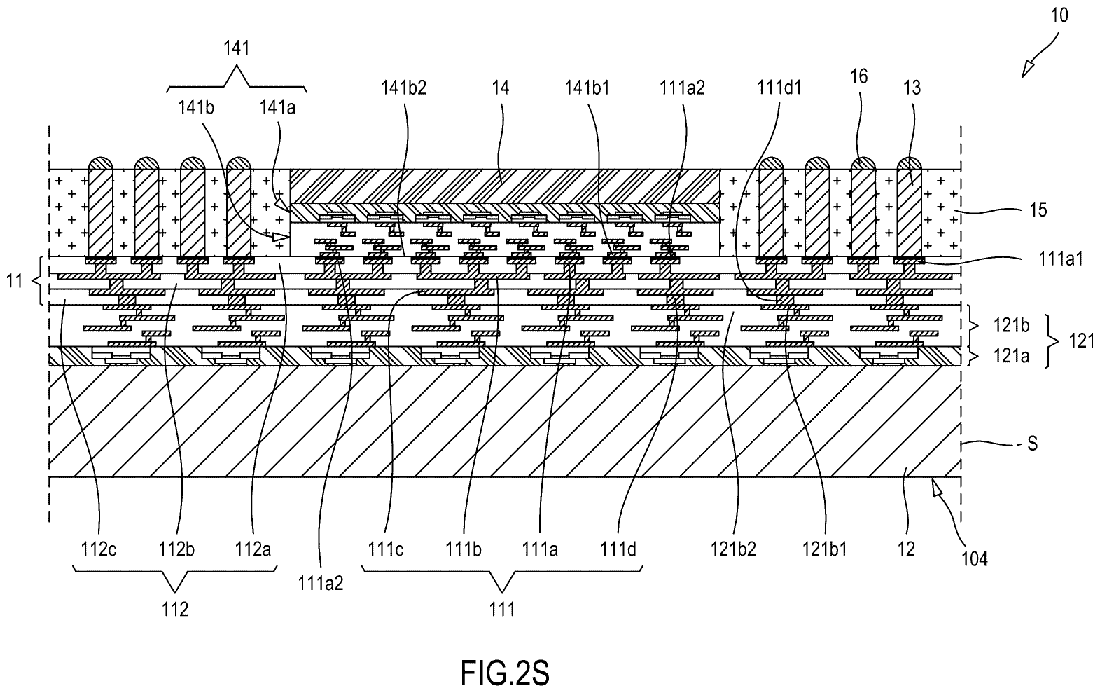

FIGS. 2A to 2S show an example method for manufacturing electronic device 10 in cross-sectional views. FIG. 2A shows a cross-sectional view of electronic device 10 at an early stage of manufacture. In the example shown in FIG. 2A, seed layer 102 is provided on the upper side of temporary carrier 101.

Seed layer 102 can be provided to cover the upper side of temporary carrier 101 and can be coupled to the upper side of temporary carrier 101. In some examples, seed layer 102 can be provided by electroless plating, electroplating, sputtering, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). In some examples, seed layer 102 can comprise a seed, a conductive layer, or a buffer layer. In some examples, seed layer 102 can comprise Ti, TiW, W, Cr, Al, Ni, Au, Ag, or Cu. In some examples, the thickness of seed layer 102 can range from approximately 0.01 micrometers (μm) to approximately 0.2 μm.

Temporary carrier 101 can be a substantially planar plate. In some examples, temporary carrier 101 can comprise or be referred to as a plate, a board, a wafer, a panel, or a strip. For example, temporary carrier 101 can be provided as a wafer. In some examples, the thickness of temporary carrier 101 can range from approximately 300 μm to approximately 1000 μm, and the width of temporary carrier 101 can range from approximately 100 millimeters (mm) to approximately 300 mm. Temporary carrier 101 can support multiple electronic devices 10 during processing.

In some examples, temporary carrier 101 can comprise a temporary bond layer provided on the upper side of temporary carrier 101. Seed layer 102 can be provided over the temporary bond layer. The temporary bond layer can be provided on the surface of temporary carrier 101 by a coating method such as spin coating, doctor blade coating, casting, painting, spray coating, slot die coating, curtain coating, slide coating, or knife over edge coating, a printing method such as screen printing, pad printing, gravure printing, flexography printing, or offset printing, or an inkjet printing method, an intermediate technology between coating and printing, or can be provided by direct attachment of a bonding film or bonding tape. In some examples, the temporary bond layer can comprise or be referred to as a temporary bonding film, a temporary bonding tape, or a temporary adhesive coating. For example, the temporary bonding layer can be a heat release tape (or film) or an optical release tape (or film), wherein the adhesive strength is weakened or removed by heat or light, respectively. The temporary bond layer can facilitate separation of RDL substrate 11 from temporary carrier 101, as shown in FIG. 2L to 2M.

FIG. 2B shows a cross-sectional view of electronic device 10 at a later stage of manufacture. In the example shown in FIG. 2B, photoresist 103 is provided on the upper side of seed layer 102.

Photoresist 103 can be provided on the upper side of seed layer 102 as a liquid or film. Photoresist 103 can be provided on the upper side of seed layer 102 by coating. Photoresist 103 can be provided with patterns and that define vias 1031 exposing the upper side of seed layer 102. Photoresist 103 can expose seed layer 102 in areas where proximate conductive pattern 111a (FIG. 2C) is provided in future processing steps. Photoresist 103 can cover seed layer 102 in an area where proximate passivation 112a (FIG. 2F) is provided in future processing steps. In some examples, vias 1031 can comprise or be referred to as openings, apertures, or holes. In some examples, the thickness of photoresist 103 can range from approximately 0.3 μm to approximately 1 μm.

FIG. 2C shows a cross-sectional view of electronic device 10 at a later stage of manufacture. In the example shown in FIG. 2C, proximate conductive pattern 111a is provided on the upper side of seed layer 102.

Proximate conductive pattern 111a can be coupled to a portion of seed layer 102 exposed through vias 1031 defined through photoresist 103. Proximate conductive pattern 111a can be provided through plating using seed layer 102 as a seed. Proximate conductive pattern 111a can be provided as patterns in vias 1031 of photoresist 103. Proximate conductive pattern 111a can comprise or be referred to as conductive layers, traces, pads, lands, TVS, TGS, vias, redistribution layers (RDLs), wiring patterns, or circuit patterns. In some examples, proximate conductive pattern 111a can comprise silver, copper, gold, silver, or nickel. In some examples, proximate conductive pattern 111a can be provided by electrolytic plating. In some examples, the overall thickness of proximate conductive pattern 111a can range from approximately 0.15 μm to approximately 0.3 μm.

FIG. 2D shows a cross-sectional view of electronic device 10 at a later stage of manufacture. In the example shown in FIG. 2D, photoresist 103 and portions of seed layer 102 are removed.

After removing photoresist 103, portions of seed layer 102 can be removed using proximate conductive pattern 111a as a mask. For example, the portions of seed layer 102 exposed through proximate conductive pattern 111a (i.e., not cover by proximate conductive pattern 111a) can be removed through etching. Removal of seed layer 102 can expose the upper side of temporary carrier 101. Remaining portions of seed layer 102 can be located between proximate conductive pattern 111a and temporary carrier 101. Seed layer 102 can have patterns similar to or the same as proximate conductive pattern 111a and can be included in proximate conductive pattern 111a. In some examples, the thickness of proximate conductive pattern 111a can range from approximately 0.15 μm to approximately 0.3 μm.

FIG. 2E shows a cross-sectional view of electronic device 10 at a later stage of manufacture. In the example shown in FIG. 2E, proximate passivation 112a is provided over temporary carrier 101 and proximate conductive pattern 111a.

Proximate passivation 112a can be provided to cover the upper sides of temporary carrier 101 and proximate conductive pattern 111a. Apertures can be provided in proximate passivation 112a to expose portions of proximate conductive pattern 111a. Proximate passivation 112a can be coupled to and/or located on the upper side of temporary carrier 101 and on the sidewalls and upper side of proximate conductive pattern 111a. Proximate passivation 112a can be made of an inorganic dielectric material. For example, proximate passivation 112a can be made of an oxide or nitride such as SiO2, SiCN, SiN, or Al2O3. Proximate passivation 112a can be provided by spin coating, spray coating, dip coating, rod coating, PVD, CVD, or any other suitable deposition process. The thickness of proximate passivation 112a can range from approximately 0.1 μm to approximately 0.5 μm.

FIG. 2F shows a cross-sectional view of electronic device 10 at a later stage of manufacture. In the example shown in FIG. 2F, intermediate conductive pattern 111b is provided over proximate passivation 112a and proximate conductive pattern 111a.

Intermediate conductive pattern 111b can be coupled to proximate conductive pattern 111a. For example, intermediate conductive pattern 111b can contact the upper side of proximate conductive pattern 111a exposed through the apertures in proximate passivation 112a. Intermediate conductive pattern 111b can fill the apertures defined in proximate passivation 112a and can extend over the upper side of proximate passivation 112a. Intermediate conductive pattern 111b can be electrically coupled to proximate conductive pattern 111a. Intermediate conductive pattern 111b can have elements, features, materials, or manufacturing methods similar to or the same as those of proximate conductive pattern 111a.

FIG. 2G shows a cross-sectional view of electronic device 10 at a later stage of manufacture. In the example shown in FIG. 2G, intermediate passivation 112b is provided over intermediate conductive pattern 111b and proximate passivation 112a.

Intermediate passivation 112b can be provided covering the upper sides of intermediate conductive pattern 111b and proximate passivation 112a. Apertures can be provided in intermediate passivation 112b to expose portions of intermediate conductive pattern 111b. Intermediate passivation 112b can be made of an organic dielectric material (e.g., polyimide (PI), benzocyclobutene (BCB), polybenzoxazole (PBO), resin or an Ajinomoto buildup film (ABF)) or an inorganic dielectric material (e.g., SiO2, SiCN, SiN, or Al2O3). Intermediate passivation 112b can have elements, features, materials, or manufacturing methods similar to or the same as those of proximate passivation 112a.

FIG. 2H shows a cross-sectional view of electronic device 10 at a later stage of manufacture. In the example shown in FIG. 2H, intermediate conductive pattern 111c is provided over intermediate conductive pattern 111b and intermediate passivation 112b.

Intermediate conductive pattern 111c can be coupled to intermediate conductive pattern 111b. For example, intermediate conductive pattern 111c can contact the top side of intermediate conductive pattern 111b, which is exposed through the apertures in intermediate passivation 112b. Intermediate conductive pattern 111c can fill the apertures defined in intermediate passivation 112b and can extend over the upper side of intermediate passivation 112b. Intermediate conductive pattern 111c can have elements, features, materials, or manufacturing methods similar to or the same as those of proximate conductive pattern 111a.

FIG. 2I shows a cross-sectional view of electronic device 10 at a later stage of manufacture. In the example shown in FIG. 2I, distal passivation 112c is provided over intermediate conductive pattern 111c and intermediate passivation 112b.

Distal passivation 112c can be provided covering the upper sides of intermediate conductive pattern 111c and intermediate passivation 112b. In some examples, distal passivation 112c can be provided with an initial thickness that is approximately twice the thickness of proximate passivation 112a. Distal passivation 112c can then be planarized, for example, using chemical-mechanical polishing (CMP). The thickness of distal passivation 112c after planarization can be similar to or the same as proximate passivation 112a. Apertures exposing intermediate conductive pattern 111c can be provided in distal passivation 112c. Distal passivation 112c can comprise an inorganic dielectric material (e.g., SiO2, SiCN, SiN, or Al2O3). Distal passivation 112c can comprise elements, features, materials, or manufacturing methods similar to or the same as those of proximate passivation 112a.

FIG. 2J shows a cross-sectional view of electronic device 10 at a later stage of manufacture. In the example shown in FIG. 2J, distal conductive pattern 111d is provided over intermediate conductive pattern 111c.

Distal conductive pattern 111d can be coupled to intermediate conductive pattern 111c. For example, distal conductive pattern 111d can contact the top side of intermediate conductive pattern 111c, which is exposed through the apertures in distal passivation 112c. Distal conductive pattern 111d can fill the apertures defined by distal passivation 112c. The upper sides of distal conductive pattern 111d can be coplanar with the upper side of distal passivation 112c. In some examples, the upper side of distal conductive pattern 111d can be recessed (e.g., dished) relative to the upper side of distal passivation 112c. Distal conductive pattern 111d can have elements, features, materials, or manufacturing methods similar to or the same as those of proximate conductive pattern 111a.

In some examples, distal conductive pattern 111d can comprise or be referred to as distal terminals 111d1 of RDL substrate 11. Distal terminals 111d1 of conductive structure 111 can be provided along the upper side of RDL substrate 11 and can be spaced apart from each other in a row and/or column arrangement.

In some examples, proximate conductive pattern 111a can comprise or be referred to as proximate terminals 111a1 and 111a2 of conductive structure 111. Proximate terminals 111a1 and 111a2 can be provided along the lower side of RDL substrate 11 and can be spaced apart from each other in a row and/or column arrangement. Proximate terminals 111a1 and 111a2 can comprise first proximate terminals 111a1 located in the edge area on the lower side of RDL substrate 11 and second proximate terminals 111a2 located in the central area of RDL substrate 11. For example, first proximate terminals 111a1 can be closer to the lateral side of RDL substrate 11 as compared to second proximate terminals 111a2.

In accordance with various examples, RDL substate 11 can comprise any number (e.g., zero to ten) of intermediate conductive patterns 111b or 111c between proximate conductive pattern 111a and distal conductive pattern 111d. For example, while conductive structure 111 is shown comprising four conductive patterns 111a, 111b, 111c, 111d, and dielectric structure 112 is shown comprising three passivations 112a, 112b, 112c, it is contemplated and understood that RDL substrate 11 can include fewer or more conductive patterns and/or passivations. For example, conductive structure 111 can be formed without intermediate conductive patterns or with one or more intermediate conductive pattern(s) between proximate conductive pattern 111a and distal conductive pattern 111d. Similarly, dielectric structure 112 can have no intermediate passivation layers or one or more intermediate passivation layers between proximate passivation 112a and distal passivation 112c. In some examples, the overall thickness of RDL substrate 11 can range from approximately 0.6 μm to approximately 50 μm.

In some examples, RDL substrate 11 can be a redistribution layer (“RDL”) substrate. RDL substrates can comprise one or more conductive redistribution layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers. RDL substrates can define respective conductive redistribution patterns or traces configured to collectively (a) fan-out electrical traces outside the footprint of the electronic device, and/or (b) fan-in electrical traces within the footprint of the electronic device.

In some examples, conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask.

In some examples, the dielectric layers of the RDL substrate can be patterned with a photo-patterning process and can include a photolithographic mask through where light is exposed to photo-pattern desired features such as vias in the dielectric layers. One or more of the dielectric layers can be made from photo-definable dielectric materials such as, for example, PI, BCB, or PBO. Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and can interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples, at least the proximate and distal passivation layers of the RDL substrate can comprise one or more inorganic dielectric layers. Some examples of inorganic dielectric layer(s) can comprise silicon nitride (Si3N4), silicon oxide (SiO2), and/or silicon oxynitride (SiON). The inorganic dielectric layer(s) can be formed by growing the inorganic dielectric layers using an oxidation or nitridization process instead of using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4, and these types of RDL substrates can comprise or be referred to as a coreless substrate. Other substrates in the present disclosure can also comprise an RDL substrate.

In some examples, RDL substrate 11 can be a pre-formed substrate. The pre-formed substrate can be manufactured prior to attachment to an electronic device and can comprise dielectric layers interleaved between respective conductive layers. The conductive layers can comprise copper and can be formed using an electroplating process. The dielectric layers can be relatively thicker non-photo-definable layers, can be attached as a pre-formed film rather than as a liquid, and can include a resin with fillers such as strands, weaves, and/or other inorganic particles for rigidity and/or structural support. Since the dielectric layers are non-photo-definable, features such as vias or openings can be formed by using a drill or laser. The pre-formed substrate can include a permanent core structure or carrier such as, for example, a dielectric material comprising BT or FR4, and dielectric and conductive layers can be formed on the permanent core structure. The pre-formed substrate can be referred to as a printed circuit board (PCB) or a laminate substrate. Such pre-formed substrate can be formed through a semi-additive or modified-semi-additive process. Other substrates in the present disclosure can also comprise a pre-formed substrate.

FIG. 2K shows a cross-sectional view of electronic device 10 at a later stage of manufacture. In the example shown in FIG. 2K, die wafer 104 can be provided on the upper side of RDL substrate 11.

Die wafer 104 can comprise a plurality of wafer components 12. For example, die wafer 104 can be a semiconductor wafer having a plurality of semiconductor die separated by saw streets. In some examples, die wafer can be a reconstituted wafer comprising a plurality of known good semiconductor die aggregated and reconstituted (e.g., encapsulated) to form die wafer 104 (e.g., encapsulant can be located between adjacent semiconductor die). Wafer component 12 can comprise or be referred to as a semiconductor die, a chip, a wafer level package (WLP), or a wafer-level fan-out (WLFO). Each wafer component 12 of die wafer 104 comprises wafer active area 121 located on the lower side of wafer component 12. In some examples, wafer active area 121 can comprise or be referred to as an active side of wafer component 12. Wafer active area 121 can comprise wafer FEOL area 121a located on the lower side of wafer component 12 and wafer BEOL area 121b located on the lower side of wafer FEOL area 121a.

Wafer FEOL area 121a can comprise various layers and patterns to generate devices such as transistors, MOSFETs, CMOS transistors (e.g., shallow trench isolation (STI), gate modules, source and drain modules, capacitors, or resistors). For example, wafer FEOL area 121a can be provided on the lower side of wafer component 12 through oxidation, diffusion, ion implantation, a lithography process, etc.

Wafer BEOL area 121b can comprise a conductive structure and a dielectric structure for connecting elements provided in wafer FEOL area 121a. The conductive structure can comprise vias being vertical conductive structures, and traces being horizontal conductive structures. The dielectric structure can be made of an inorganic dielectric material. Wafer BEOL area 121b can form layers through CVD and/or PVD, and each layer can be patterned through lithography and etching. In some examples, the thickness of wafer active area 121 can range from approximately 0.1 μm to approximately 0.6 μm.

The conductive structures located at the lowermost side of wafer BEOL area 121b can comprise or be referred to as wafer terminals 121b1. The portion (e.g., layer) of the dielectric structure located at lowermost side of wafer BEOL area 121b can comprise or be referred to as wafer-external passivation 121b2. Wafer-external passivation 121b2 can be made of an oxide or nitride such as SiO2, SiCN, SiN, or Al2O3. The thickness of wafer-external passivation 121b2 can vary in response to the number of metal layers. In some examples, thickness of wafer-external passivation 121b2 can range from approximately 0.25 μm to approximately 13 μm.

In various examples, the lower sides of wafer terminals 121b1 can be coplanar with the lower side of wafer-external passivation 121b2. In some examples, the lower sides of wafer terminals 121b1 can be recessed (e.g., dished) relative to the lower side of wafer-external passivation 121b2. Die wafer 104 is disposed over RDL substrate 11 such that wafer terminals 121b1 of die wafer 104 are vertically aligned and/or overlap the upper sides of distal terminals 111d1 of RDL substrate 11. The thickness of die wafer 104 can range from approximately 300 μm to approximately 1000 μm.

FIG. 2L shows a cross-sectional view of electronic device 10 at a later stage of manufacture. In the example shown in FIG. 2L, die wafer 104 is bonded to RDL substrate 11.

In accordance with various examples, wafer terminals 121b1 of die wafer 104 can be bonded to distal terminals 111d1 of RDL substrate 11, and wafer-external passivation 121b2 of die wafer 104 can be bonded to distal passivation 112c of RDL substrate 11. In accordance with various examples, a bond interface 105 being formed between external passivation 121b2 and distal passivation 112c, and between wafer terminals 121b1 and distal terminals 111d1.

In some examples, bonding between die wafer 104 and RDL substrate 11 can be achieved through a hybrid bonding process. For example, the bond between wafer-external passivation 121b2 and distal passivation 112c can initially start as Van der Waals bonds that progress to covalent bonds through time and, in some examples, application of heat. With the passivation layers bonded, wafer terminals 121b1 and distal terminals 111d1 can be urged into contact with one another, such that a direct, solderless bond between wafer terminals 121b1 and distal terminals 111d1 can be formed.

In accordance with various examples, the bonding between wafer-external passivation 121b2 and distal passivation 112c can be achieved at relatively low temperatures through surface activation of wafer-external passivation 121b2 and distal passivation 112c prior to bonding. In some examples, surface activation of wafer-external passivation 121b2 and distal passivation 112c can include generating hydrogen (H) on the surfaces of wafer-external passivation 121b2 and distal passivation 112c through plasma treatment, oxygen (O) particles separated from water or air during plasma treatment can bind to the hydrogen (H) on the surfaces of wafer-external passivation 121b2 and distal passivation 112c, and hydroxyl (OH) groups can be induced on the surfaces of wafer-external passivation 121b2 and distal passivation 112c. With the surfaces of wafer-external passivation 121b2 and distal passivation 112c “activated” bonding can occur at lower temperatures. For example, the initial Van der Waals bonds can form at room temperature (e.g., at temperatures ranging from approximately 20° C. to approximately 30° C.). Covalent bonds between wafer-external passivation 121b2 and distal passivation 112c can also be formed at room temperature; however, in various embodiments, an annealing process can be performed to decrease the time associated with covalent bond formation. As used herein to describe temperatures, the term approximately can mean +/−5%, +/−10%, +/−15%, +/−20%, or +/−25%.

With wafer-external passivation 121b2 bonded to distal passivation 112c, wafer terminals 121b1 of die wafer 104 can be bonded to distal terminals 111d1 of RDL substrate 11. In some examples, an annealing process can be performed to bond wafer terminals 121b1 and distal terminals 111d1. The annealing process can be performed during or after the bonding of wafer-external passivation 121b2 to distal passivation 112c. The temperature of the annealing process can range from approximately 25° C. to approximately 200° C. and the time can range from 0.5 to 20 hours. In some examples, the annealing process can include applying a temperature of approximately 150° C. for between 1.0 to 3.0 hour(s). The annealing process can improve bonding strength, reduce bonding time, and increase yields by inducing the conversion of the Van der Walls bonds to covalent bonds and/or inducing the thermal expansion of wafer terminals 121b1 and distal terminals 111d1.

In some examples, the direct bond between wafer terminals 121b1 and distal terminals 111d1 can comprise or be referred as a fusion bond or a solderless bond. In some examples, the direct bond can comprise grain growth of the material of wafer terminals 121b1 and the material of distal terminals 111d1 into each other. In some examples, the direct bond can be established by pressure caused by wafer terminals 121b1 and distal terminals 111d1 expanding towards each other due to heat applied during annealing (e.g., thermal expansion). For example, wafer terminals 121b1 and distal terminals 111d1 can be bonded together as their respective surfaces contact one another and metals diffuse from wafer terminals 121b1 and distal terminals 111d1 across bond interface 105. It is contemplated and understood that bond interface 105 may not be visible in the final device, as the covalent bonds formed between wafer-external passivation 121b2 and distal passivation 112c can make wafer-external passivation 121b2 indistinguishable from distal passivation 112c.

In some examples, after wafer-external passivation 121b2 of die wafer 104 and distal passivation 112c of RDL substrate 11 are bonded, wafer terminals 121b1 and distal terminals 111d1 can be spaced apart from each other by a void. In response to application of an interconnect bonding temperature (e.g., the annealing process), wafer terminals 121b1 and distal terminals 111d1 can expand to fill this void and contact and bond with each other. The initial void between wafer terminals 121b1 and distal terminals 111d1 can compensate for the difference in thermal expansions of terminals 121b1, 111d1 and passivations 121b2, 112c.

FIG. 2M shows a cross-sectional view of electronic device 10 at a later stage of manufacture. In FIG. 2M, die wafer 104 and RDL substrate 11 are flipped 180° relative to FIG. 2L, such that die wafer 104 is below RDL substrate 11. In the example shown in FIG. 2M, temporary carrier 101 is removed from RDL substrate 11. In some examples, a temporary bond layer (e.g., a heat release layer or optic release layer) of temporary carrier 101 can facilitate removal of temporary carrier 101 from RDL substrate 11. Removal of temporary carrier 101 can expose proximate conductive pattern 111a and proximate passivation 112a of RDL substrate 11. For example, the upper side of proximate conductive pattern 111a and proximate passivation 112a of RDL substrate 11 can be exposed. It is understood that seed 102 (FIG. 2D) can be considered part of proximate conductive pattern 111a.

FIG. 2N shows a cross-sectional view of electronic device 10 at a later stage of manufacture. In the example shown in FIG. 2N, vertical interconnects 13 are provided on the upper side of RDL substrate 11.

In some examples, vertical interconnects 13 can be provided in an edge area on the upper side of RDL substrate 11. For example, vertical interconnects 13 can be provided about a perimeter of RDL substrate 11. Vertical interconnects 13 can be coupled to proximate terminals 111a1 of RDL substrate 11.

Vertical interconnects 13 can be spaced apart from each other in a row and/or column arrangement. Vertical interconnects 13 can be provided by electrolytic plating, electroless plating, sputtering, PVD, CVD, MOCVD, ALD, LPCVD, or PECVD. In some examples, vertical interconnects 13 can be made of copper, gold, silver, palladium, or nickel. Vertical interconnects 13 can comprise posts, pillars, vertical wires, bumps, or solder-coated-metallic-core-balls. In some examples, the height of vertical interconnect 13 can range from approximately 50 μm to approximately 400 μm.

FIG. 2O shows a cross-sectional view of electronic device 10 at a later stage of manufacture. In the example shown in FIG. 2O, one or more electronic component(s) 14 is/are provided over the upper side of RDL substrate 11.

Electronic component 14 can comprise component active area 141. Active area 141 is oriented toward RDL substrate 11. Electronic component 14 can comprise or be referred to as a semiconductor die, a chip, or a package. In some examples, component active area 141 can comprise or be referred to as an active side of electronic component 14. Component active area 141 can comprise component FEOL area 141a located at the lower side of electronic component 14 and component BEOL area 141b located on the lower side of component FEOL area 141a. Component FEOL area 141a and component BEOL area 141b of component active area 141 can have elements, features, materials, or manufacturing methods similar to or the same as those of wafer FEOL area 121a and wafer BEOL area 121b of wafer active area 121, respectively.

The conductive structure located at the lowermost side of component BEOL area 141b can comprise or be referred to as component terminals 141b1. The dielectric structure (or layer) located at the lowermost side of component BEOL area 141b can comprise or be referred to as component-external passivation 141b2. In various examples, component-external passivation 141b2 can comprise an inorganic material. For example, component-external passivation 141b2 can comprise oxide or nitride such as SiO2, SiCN, SiN, or Al2O3. In some examples, component external passivation 141b2 can have a thickness of approximately 0.2 μm to approximately 13 μm. The lower side of component terminals 141b1 can be coplanar with the lower side of component-external passivation 141b2. In some examples, the lower side of component terminals 141b1 can be recessed (e.g., dished) with respect to the lower side of component-external passivation 141b2. In some examples, pick-and-place equipment can pick up electronic component 14 and locate electronic component 14 over RDL substrate 11 such that component terminals 141b1 are vertically aligned with second proximate terminals 111a2. In some examples, the thickness of electronic component 14 can be greater than the thicknesses of vertical interconnects 13. In some examples, the thickness of electronic component 14 can range from approximately 300 μm to approximately 1000 μm. In some examples, the area (or footprint) of electronic component 14 can be 1 mm×1 mm to 30 mm×30 mm.

FIG. 2P shows a cross-sectional view of electronic device 10 at a later stage of manufacture. In the example shown in FIG. 2P, electronic component 14 is bonded to the upper side of RDL substrate 11.

In accordance with various examples, component terminals 141b1 of electronic component 14 can be coupled to proximate terminals 111a2 of RDL substrate 11, and component-external passivation 141b2 of electronic component 14 can be coupled to proximate passivation 112a of RDL substrate 11. In some examples, a hybrid bonding process is used to bond component terminals 141b1 to proximate terminals 111a2, and component-external passivation 141b2 to proximate passivation 112a. The hybrid bonding process can be similar to or the same as the hybrid bonding described above for bonding die wafer 104 and RDL substrate 11.

A bond interface 106 can be formed between RDL substrate 11 and electronic component 14. Bond interface 106 can be between component-external passivation 141b2 and proximate passivation 112a, and between component terminals 141b1 and proximate terminals 111a2. The plane of bond interface 106 can be substantially parallel to the plane of bond interface 105. It is contemplated and understood that bond interface 106 may not be visible in the final device, as the covalent bonds formed between component-external passivation 141b2 and proximate passivation 112a can make component-external passivation 141b2 indistinguishable from proximate passivation 112a.

In various examples, electronic component 14 can be located in the central area of the upper side of RDL substrate 11. The side walls of electronic component 14 can be spaced apart from vertical interconnects 13. Electronic component 14 can be electrically coupled to vertical interconnects 13 through RDL substrate 11 and wafer BEOL region 121b of wafer component 12.

FIG. 2Q shows a cross-sectional view of electronic device 10 at a later stage of manufacture. In the example shown in FIG. 2Q, encapsulant 15 is provided over electronic component 14, vertical interconnects 13, and RDL substrate 11.

In various examples, encapsulant 15 can comprise or be referred to as a body or a molding. In some examples, encapsulant 15 can comprise an epoxy mold compound, a resin, or an organic polymer with an inorganic filler, a curing agent, a catalyst, a coupling agent, a colorant, or a flame retardant. Encapsulant 15 can and can be provided by compression molding, transfer molding, liquid body molding, vacuum lamination, paste printing, or film assist molding.

In some examples, encapsulant 15 can be coupled to the upper side of RDL substrate 11, the upper side and sidewalls of electronic component 14, and the upper side and sidewalls of vertical interconnects 13. In some examples, the thickness of encapsulant 15 can range from approximately 300 μm to approximately 1200 μm.

FIG. 2R shows a cross-sectional view of electronic device 10 at a later stage of manufacture. In the example shown in FIG. 2R, an upper portion of encapsulant 15 and of electronic component 14 are removed, and the upper sides of vertical interconnects 13 are exposed.

In accordance with various examples, the upper portion of encapsulant 15 can be removed by grinding, for example. In some examples, when the upper portion of encapsulant 15 is removed, an upper portion of electronic component 14 and an upper portion of vertical interconnects 13 can also be removed. The upper side of encapsulant 15, the upper side of electronic component 14, and the upper side of vertical interconnects 13 can be coplanar. In some examples, the final thickness of encapsulant 15 can range from approximately 40 μm to approximately 350 μm.

FIG. 2S shows a cross-sectional view of electronic device 10 at a later stage of manufacture. In the example shown in FIG. 2S, device interconnects 16 can be provided on the upper side of vertical interconnects 13.

In various examples, device interconnects 16 can be coupled to vertical interconnects 13. Device interconnects 16 can be electrically coupled to electronic component 14 through vertical interconnects 13, RDL substrate 11, and wafer BEOL region 121b of wafer component 12, which can minimize or reduce the distance or complexity of a communication path for electrical current, as compared to packages that include through TSV, for example.

In some examples, device interconnects 16 can comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, after forming a conductive material containing a solder on the upper sides of vertical interconnects 13 through a ball drop method, device interconnects 16 can be provided through a reflow process. Device interconnects 16 can comprise or be referred to as conductive balls such as solder balls, conductive pillars such as copper pillars, or conductive posts with solder caps provided on the copper pillars. In some examples, a height of device interconnects 16 can range from approximately 1 μm to approximately 500 μm. In some examples, device interconnects 16 can be referred to as outward input/output terminals of electronic device 10.

After providing device interconnects 16, a singulation process can be performed to saw die wafer 104 and RDL substrate 11 along scribe lines (or saw streets) S, thereby separating individual electronic devices 10 from one another. In some examples, a diamond blade or laser beam can be utilized for singulation. Singulation can include cutting or sawing through encapsulant 15, RDL substrate 11, and die wafer 104. After singulation the lateral sides of encapsulant 15, RDL substrate 11 and wafer component 12 can be coplanar.

Electronic device 10 can comprise RDL substrate 11, wafer component 12, vertical interconnects 13, electronic component 14, encapsulant 15, and device interconnects 16. In electronic device 10, RDL substrate 11 and wafer component 12 can be bonded to each other, and RDL substrate 11 and electronic component 14 can be bonded to each other. The bonding can be hybrid bonding, without a separate soldering process, thereby improving a bonding strength and an electrical connection relationship. Solderless bonding can also enable improved (e.g., decreased) pitch for conductive layers and interconnections. The reduced temperatures associated with hybrid bonding can also reduce occurrences of defects, which can improve electrical performance and increase yields.

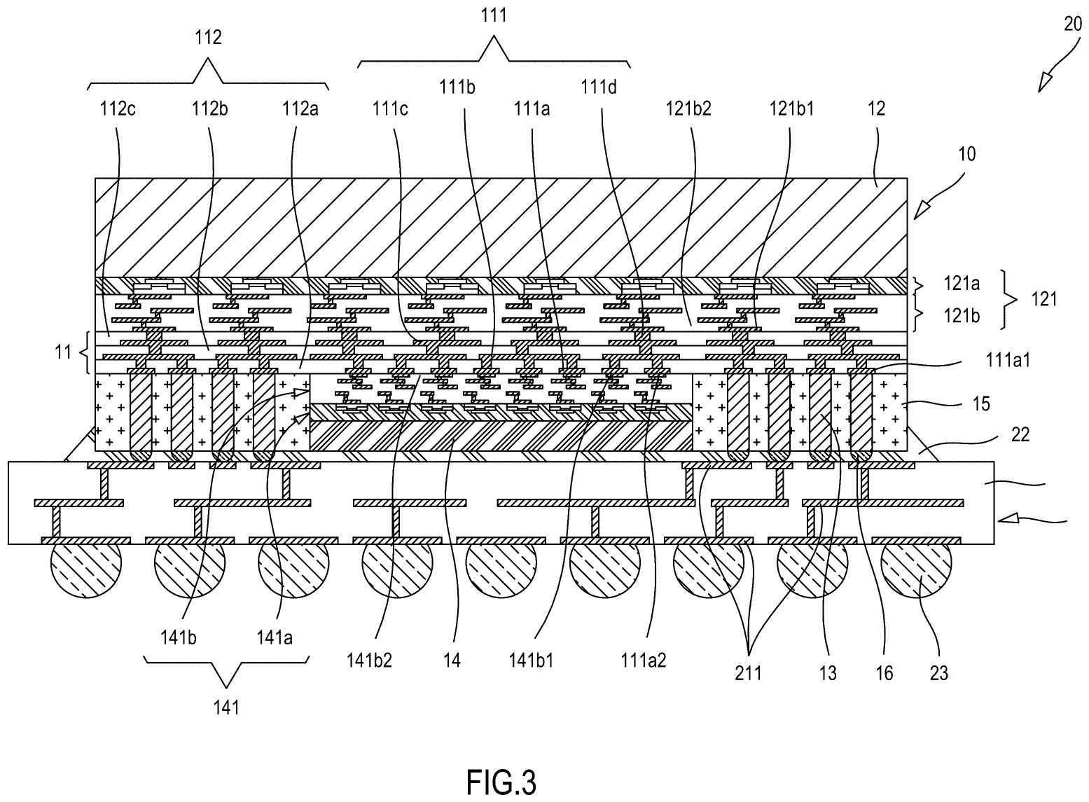

FIG. 3 shows a cross-sectional view of an electronic device 20. In the example shown in FIG. 3, electronic device 20 can comprises electronic device 10, base substrate 21, underfill 22, and external interconnects 23.

Electronic device 10 can be coupled to base substrate 21. Underfill 22 can be disposed between electronic device 10 and base substrate 21. External interconnects 23 can be provided on the side of base substrate that is opposite electronic device 10.

Base substrate 21 can comprise dielectric structure 212 and conductive structure 211. In some examples, dielectric structure 212 can comprise or be referred to as one or more dielectric layers. For example, the one or more dielectric layers can comprise core layers, polymer layers, pre-preg layers, or solder mask layers, which can be stacked over each other. One or more layers or elements of conductive structure 211 can be interposed or embedded between the one or more layers of dielectric structure 212. The upper and lower sides of dielectric structure 212 can be substrate inner side and substrate outer side of base substrate 21, respectively. In some examples, dielectric structure 212 can comprise a polymer, PI, BCB, PBO, BT, ABF or resin. In some examples, the thickness of dielectric structure 212 can range from approximately 15 μm to 60 μm.

Conductive structure 211 can comprise one or more conductive layers and defines conductive paths with elements such as traces, pads, vias, and wiring patterns. Conductive structure 211 can comprise inward terminals provided on substrate top side of base substrate 21, outward terminals provided on substrate bottom side of base substrate 21, and conductive paths extending through dielectric structure 212. In some examples, inward terminals or outward terminals can comprise or be referred to as conductors, conductive materials, substrate lands, conductive lands, substrate pads, wiring pads, connection pads, micro pads, or under-bump-metallurgies (UBMs). Inward terminals of conductive structure 211 can be coupled to and electrically connected to device interconnects 16 of electronic device 10. In some examples, conductive structure 211 can comprise copper, iron, nickel, gold, silver, palladium, or tin.

In some examples, base substrate 21 can comprise or be referred to as a rigid substrate, a laminate substrate, a ceramic substrate, a glass substrate, a silicon substrate, a printed circuit board, a multilayer substrate, or a molded lead frame. In some examples, base substrate 21 can comprise or be referred to as an RDL substrate, a buildup substrate, or a coreless substrate. In some example, base substrate 21 can have an area varying according to the area of electronic device 10 and can have an area of about 3 mm×3 mm to about 110 mm×110 mm. Base substrate 21 can have a thickness varying according to the thickness of electronic device 10 and can have a thickness of about 0.1 mm to about 7 mm. In some examples, base substrate 21 can have elements, features, materials, or manufacturing methods similar to or the same as those of RDL substrate 11.

Underfill 22 can be located between electronic device 20 and base substrate 21. Underfill 22 can be coupled to the lower side of electronic device 20 and the upper side of base substrate 21. Underfill 22 can be coupled to the lower side of electronic component 14 of electronic device 20, the lower side of encapsulant 15, and the lower sides of device interconnects 16. Underfill 22 can be coupled to dielectric structure 212 and conductive structure 211 on the upper side of base substrate 21. Underfill 22 can comprise or be referred to as a dielectric layer or a nonconductive paste. Underfill 22 can be free of inorganic fillers. In some examples, underfill 22 can comprise or be referred to as capillary underfill (CUF), nonconductive paste (NCP), nonconductive film (NCF), anisotropic conductive film (ACF), or anisotropic conductive paste (ACP).

In some examples, after electronic device 10 is provided over base substrate 21, electronic device 10 can be coupled to base substrate 21, and underfill 22 can then be cured. Underfill 22 tends to prevent electronic device 10 from being separated from base substrate 21 against physical and chemical impacts.

External interconnects 23 can be coupled to conductive structure 211 exposed on the lower side of base substrate 21. In some examples, external interconnects 23 can have elements, features, materials, or manufacturing methods similar to or the same as those of device interconnects 16. In some examples, external interconnects 23 can be referred to as input/output terminals of electronic device 20.

Various example electronic devices may include solderless bonds to improve pitch and electronic communication. Example electronic device may also include multiple hybrid bond interfaces. OSAT manufactured F2B devices can include an I/O wafer disposed at an outer side of an electronic device and a compute wafer may buried beneath the I/O wafer. Pre-formed active devices can be coupled to opposite sides of an RDL substrate using hybrid bonding techniques. In some examples, the resulting electronic devices can be made without TSVs.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

1. An electronic device, comprising:
a substrate comprising a distal side including a distal passivation and a distal terminal, the substrate further comprising a proximate side opposite the distal side with the proximate side including a proximate passivation, a first proximate terminal, and a second proximate terminal;
a wafer component comprising a wafer-external passivation coupled to the distal passivation and comprising a wafer terminal coupled to the distal terminal,
wherein a first bond interface is disposed between the wafer-external passivation and the distal passivation,
wherein the first bond interface is disposed between the wafer terminal and the distal terminal;
an electronic component comprising a component-external passivation coupled to the proximate passivation and comprising a component terminal coupled to the first proximate terminal,
wherein a second bond interface is disposed between the component-external passivation and the proximate passivation,
wherein the second bond interface is disposed between the component terminal and the first proximate terminal; and
a vertical interconnect disposed lateral to a side of the electronic component and coupled to the second proximate terminal.

2. The electronic device of claim 1, further comprising:
a device interconnect coupled to the vertical interconnect; and
a base substrate coupled to the device interconnect.

3. The electronic device of claim 1, wherein the wafer component comprises an active region including:
a front-end of line (FEOL) region; and
a back-end of line (BEOL) region adjacent the FEOL region, wherein the BEOL region comprises the wafer-external passivation and the wafer terminal.

4. The electronic device of claim 1, wherein the wafer component comprises an input/output component, and wherein the electronic component comprises a compute component.

5. The electronic device of claim 1, wherein the electronic component comprises an active region including:
a front-end of line (FEOL) region; and
a back-end of line (BEOL) region adjacent the FEOL region, wherein the BEOL region comprises the component-external passivation and the component terminal.

6. The electronic device of claim 1, wherein the first bond interface is formed using a first hybrid bonding process, and wherein the second bond interface is formed using a second hybrid bonding process.

7. The electronic device of claim 1, further comprising an encapsulant disposed around lateral sides of the electronic component and lateral sides of the vertical interconnect.

8. The electronic device of claim 1, wherein the first proximate terminal comprises a seed layer, wherein the first bond interface is disposed between the seed layer and the component terminal.

9. The electronic device of claim 1, wherein the second proximate terminal comprises a seed layer, wherein the vertical interconnect is coupled to the seed layer.

10. An electronic device, comprising:
a redistribution layer (RDL) substrate comprising a first side and a second side opposite the first side;
a wafer component coupled to the first side of the RDL substrate, wherein a first bond interface is disposed between the wafer component and the RDL substrate, wherein the first bond interface is provided by a first hybrid bond;
an electronic component coupled to the second side of the RDL substrate, wherein a second bond interface is disposed between the electronic component and the RDL substrate, wherein the second bond interface is within a footprint of the first bond interface, wherein the second bond interface is provided by a second hybrid bond; and
a vertical interconnect disposed lateral to a sidewall of the electronic component, wherein the vertical interconnect is coupled to the RDL substrate.

11. The electronic device of claim 10, further comprising an encapsulant disposed around the electronic component and around the vertical interconnect.

12. The electronic device of claim 10, wherein the wafer component comprises an active region including:
a wafer front-end of line (FEOL) region; and
a wafer back-end of line (BEOL) region adjacent the wafer FEOL region, wherein the wafer BEOL region is coupled to the first side of the RDL substrate.

13. The electronic device of claim 12, wherein the electronic component comprises an active region including:
a component FEOL region; and
a component BEOL region adjacent the component FEOL region, wherein the component BEOL region is coupled to the second side of the RDL substrate.

14. A method of manufacturing a semiconductor device, comprising:
providing a substrate including a distal side comprising a distal passivation and a distal terminal, the substrate including a proximate side opposite the distal side with the proximate side comprising a proximate passivation, a first proximate terminal, and a second proximate terminal;
providing a wafer component including a wafer-external passivation over the distal passivation and a wafer terminal over the distal terminal;
applying a first heat to form a first bond interface between the wafer-external passivation and the distal passivation and between the wafer terminal and the distal terminal;
providing an electronic component including a component-external passivation over the proximate passivation and a component terminal over the first proximate terminal;
applying a second heat to form a second bond interface between the component-external passivation and the proximate passivation and between the component terminal and the first proximate terminal; and
providing a vertical interconnect lateral to a sidewall of the electronic component and coupled to the second proximate terminal.

15. The method of claim 14, further comprising providing an encapsulant on the sidewall of the electronic component and on sidewalls of the vertical interconnect.

16. The method of claim 14, wherein the first heat ranges from 25 degrees Celsius to 400 degrees Celsius.

17. The method of claim 14, wherein the first bond interface is formed from a hybrid bonding process comprising applying the first heat.

18. The method of claim 14, wherein the wafer component comprises a wafer active region including:
a wafer front-end of line (FEOL) region; and
a wafer back-end of line (BEOL) region adjacent the wafer FEOL region, wherein the wafer BEOL region comprises the wafer-external passivation and the wafer terminal.

19. The method of claim 18, wherein the electronic component comprises a component active region including:
a component FEOL region; and
a component BEOL region adjacent the component FEOL region, wherein the component BEOL region comprises the component-external passivation and the component terminal.

20. The method of claim 14, wherein the wafer component comprises an input/output component, and wherein the electronic component comprises a compute component.
